(19) United States
(12) Patent Application Publication
(10) Pub. No.: US 2021/0367577 A1
(43) Pub. Date: Nov. 25, 2021

(54) MICRO-ACOUSTIC DEVICE WITH REFLECTIVE PHONONIC CRYSTAL AND METHOD OF MANUFACTURE

(71) Applicant: RF360 EUROPE GMBH, Munchen (DE)

(72) Inventors: Willi AIGNER, Munchen (DE); Edgar SCHMIDHAMMER, Stein an der Traun (DE); Maximilian SCHIEK, Puchheim (DE)

(21) Appl. No.: 17/297,886

(22) PCT Filed: Dec. 16, 2019
(86) PCT No.: PCT/EP2019/085363

§ 371 Date: May 27, 2021

(30) Foreign Application Priority Data
Dec. 19, 2018 (DE) 10 2018 132 890.7

(51) Int. Cl. H03H 9/02; H03H 3/08; H03H 9/54; H03H 3/02

(52) U.S. Cl. CPC H03H 9/02118; H03H 3/08; H03H 3/02; H03H 9/02574; H03H 9/54; H03H 9/02228

(57) ABSTRACT

A micro-acoustic device comprises a confinement structure (CS) adapted to block propagation of acoustic waves of an acoustic wave resonator (TEL, PL, BEL; ES) at an operation frequency of the device to confine the acoustic waves to the acoustic path or the acoustic volume. It is proposed to use a phononic crystal material for producing the confinement structure.

The invention relates to micro-acoustic devices like SAW and BAW devices and to a method of manufacture as well. Specifically the invention provides a better confinement of the acoustic waves within these devices and thereby improving the total quality factor Q of the device.

Up to now lateral energy confinement has been done by geometrically based designs. Within BAW devices embodied as SMR device (solidly mounted resonator) acoustic isolation to the underlying substrate is done by a Bragg mirror that reflects acoustic waves by interference at lambda quarter layers where lambda is the wavelength of the acoustic wave. Within BAW devices embodied as FBAR devices the acoustic isolation to the underlying substrate is provided by an air-filled gap between the active resonator volume arranged on a membrane and the substrate.

SAW resonators or transfer filters use electrically shorted grids of reflector strips. In SAW transducers the busbars provide some lateral wave confinement by reflecting wave at the edges thereof. Additionally a transversal wave guiding profile can be implemented that is setting a transversally varying wave velocity confining the wave to the desired acoustic path.

The known acoustic confinement structures yield different problems or require complex and costly methods of manufacture.

It is an object to provide micro-acoustic devices that have improved acoustic wave confinement, reduce losses and are easy to manufacture.

These and other objects are solved by a micro-acoustic device according to claim 1 and a method according to claim 8.

Further features and advantageous embodiments are given by dependent claims.

A micro-acoustic device comprises as usual a substrate, a piezoelectric layer on a top surface of the substrate and an electrode structure on the piezoelectric layer for exciting acoustic waves at an operation frequency. Within the device the acoustic waves propagate along an acoustic path or within an active volume of the piezoelectric layer. Hence, possible micro-acoustic devices according to the invention may be embodied as SAW and BAW devices and variants like GBAW (guided buldk acoustic wave), TFSAW (thin film surface acoustic wave) or TCSAW (temperature compensated surface acoustic wave).

According to the invention a confinement structure is arranged at a position lateral to the acoustic path and/or between substrate and piezoelectric layer and/or on the top surface of the electrode structure or the piezoelectric layer. Within the confinement structure and through the structure propagation of acoustic waves at the operation frequency is prevented and hence the acoustic waves are confined to the acoustic path or to the acoustic volume. The confinement structure comprises a phononic crystal material.

Periodic structures of materials with different acoustic properties (phononic crystals) offer tunable phononic band gaps where propagation of sound is prohibited. The idea is to design and model the phononic crystal such way that the band gap complies with the operation frequency. As no acoustic wave can pass the phononic crystal it perfectly works as an acoustic mirror reflecting all impinging waves having a frequency within the band gap. The phononic crystal prevents acoustic waves having a frequency within the phononic band gap from passing the phononic crystal material independent from the direction of wave propagation. Arranging such a confinement structure at any side of the micro-acoustic device where otherwise a mode may escape the acoustic path or active volume prevents leakage of energy.

The frequency position and band width of the band gaps can be controlled by tuning the dimensions, aspect ratios, crystal structure, and material properties of the phononic crystals.

By the way such phononic crystals can be used as acoustic decoupling layers enabling novel micro acoustic designs.

The phononic crystal material used as confinement structure has a patterned structure along at least one dimension according to a periodic grid. The grid like patterned structure comprises repeating units of a first solid material embedded in a second solid material wherein first and second material are different in at least one of material, density, elastic moduli, acoustic impedance, velocity of acoustic wave, stiffness, E-modulus and hardness.

The bandgap of the phononic crystal material can be modelled by choosing a suitable size of the repeating units and by suitably choosing first and second material such that they sufficiently differ in acoustic impedance. The repeating units are arranged in a suitable mutual distance to achieve a maximum reflection by the phononic crystal at the operation frequency.

The effect leading to the bandgap is based on acoustic reflection and interference occurring at the interfaces of different repeating units and at the interfaces between different sections of first and second material. As no other property of first and second material is relevant for the effect useful combinations of a first and a second material can be chosen out of nearly all solid materials. However, production and availability of the materials must comply with the micro acoustic devices. Material selection can be made for instance with a maximum difference in acoustic impedance usually complying with the density thereof. Hence one of first and second material may be a heavy metal like e.g. W or Mo. The respective other material may then be a light-weight dielectric like a polymer or a suitable inorganic or ceramic solid like SiO₂ for example. However two metals or two dielectrics may be chosen as first and second material as well.

According to an embodiment the micro-acoustic device comprises an arrangement of BAW resonators arranged on a common substrate. Below the resonators that is between resonator and substrate a confinement structure formed as layer is arranged to avoid acoustic coupling between different BAW resonators and to avoid leakage of acoustic energy into the substrate. This layer of phononic crystal material can substitute the usual Bragg mirror.

Alternatively or in addition the confinement structure may be arranged laterally between the different BAW resonators. By doing so the BAW resonator arrangement can be provided with a plane top surface when all gaps between single BAW resonators stacks are completely filled with the phononic crystal material.

According to a further embodiment the micro-acoustic device comprises an arrangement of BAW resonators stacked one above the other on a common substrate. A confinement structure comprises a layer of phononic crystal material arranged at the interface layer between two stacked BAW resonators. As a result the stacked resonators can be completely decoupled and a space saving arrangement of different resonators can be achieved.

Employing a phononic crystal material as an acoustic decoupling layer in a device enables novel micro acoustic designs such as the concurrent production of Rx and Tx filters on the same substrate and stacking of acoustically-decoupled resonators.

In a specific embodiment the micro-acoustic device comprises a thin film SAW device having an acoustic path that is situated within the thin film piezoelectric layer and near the top of the substrate. A confinement structure of a phononic crystal material is arranged laterally adjacent to the acoustic path of the SAW device to prevent SAW from leaving the acoustic path. Additionally and similar to the BAW resonator arrangement mentioned earlier a phononic crystal material may be arranged as a confinement layer between piezoelectric and substrate.

In a filter circuit the micro-acoustic device comprises a substrate with a layer of confinement material on the top surface thereof. Different micro-acoustic RF filters are arranged on the substrate above the layer of confinement material. The RF filters comprise an Rx and a Tx filter of the same communication band that are mutually acoustically isolated by a layer of confinement material.

In a SAW device the confinement structure may be arranged on top of the piezoelectric layer or substrate adjacent to the interdigital transducers and reflectors. Alternatively the confinement structure may be embedded in the piezoelectric material near the top surface thereof.

In a BAW device the confinement structure may substitute the Bragg mirror below the resonating structure (active resonator volume). Alternatively the confinement structure may be arranged laterally adjacent the active resonator volume.

In a stacked arrangement of a bottom and a top BAW resonator the confinement structure may be arranged between the top electrode of the bottom resonator and the bottom electrode of the top resonator.

The micro-acoustic device may comprise a number of BAW resonators arranged adjacently on a common substrate to form a filter circuit. The circuiting is accomplished by a top electrode or a bottom electrode connection. This means that the interconnecting conductor is formed by structuring of top electrode or bottom electrode. According to an embodiment the respective connection is formed from an electrically conducting phononic crystal material. In this material first and second material are chosen to be electrically conductive. Conductivity may be an intrinsic property of the material or may be achieved by using a resin material filled with an electrically conductive filler like carbon or metal beads or flakes.

In the following the invention will be explained in more detail by specific embodiments and the relating figures. The figures are not drawn to scale and hence may not show real dimensions or an exact relation of depicted dimensions.

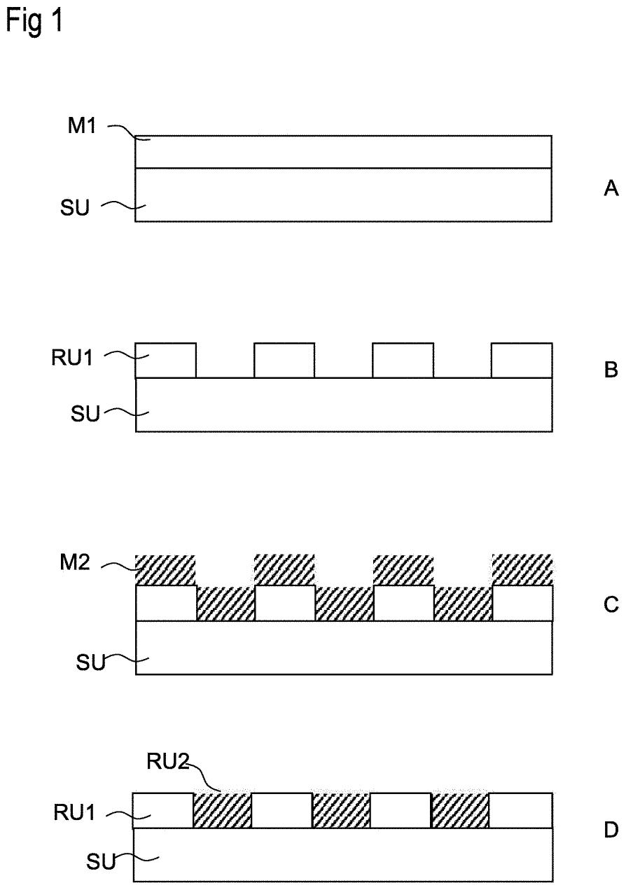

FIG. 1 shows method steps of a first method of manufacturing a confinement structure

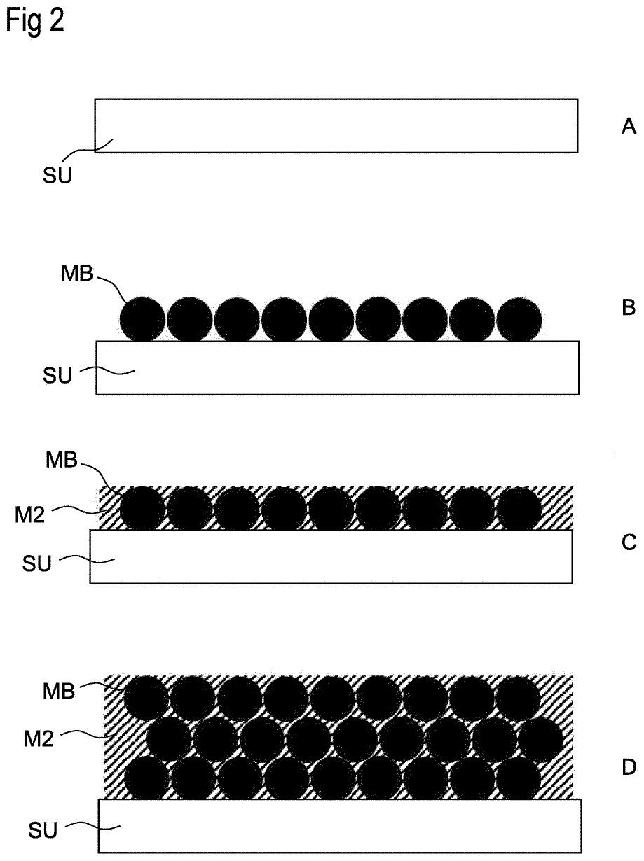

FIG. 2 shows method steps of a second method of manufacturing a confinement structure

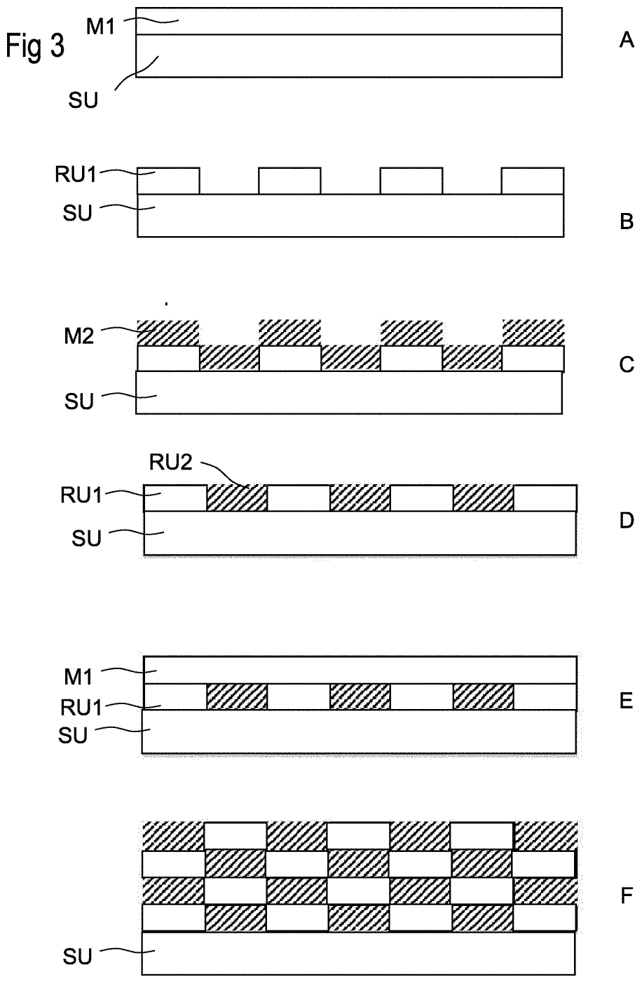

FIG. 3 shows method steps of a third method of manufacturing a confinement structure

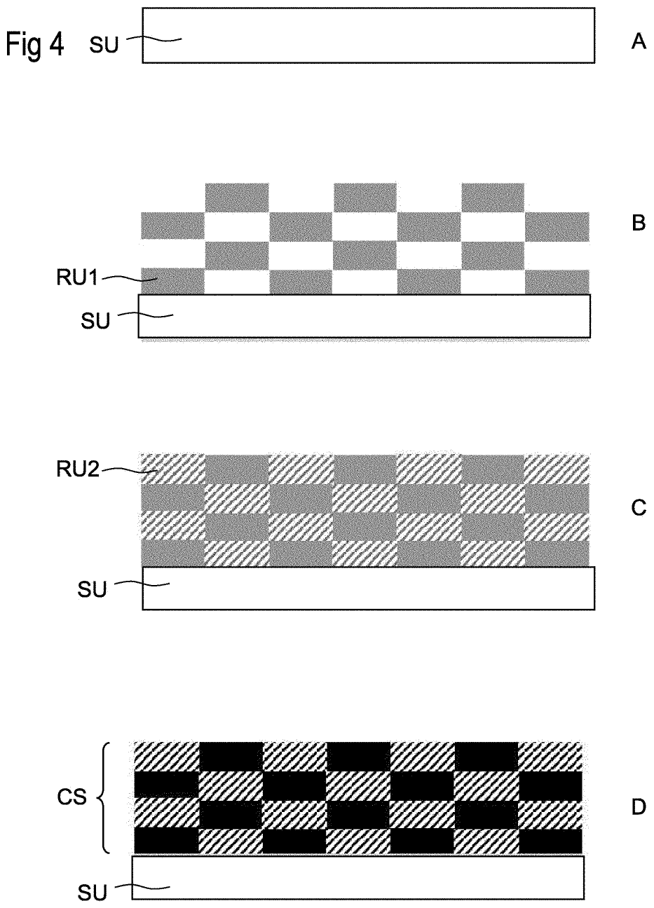

FIG. 4 shows method steps of a 3-D printing method for manufacturing a confinement structure

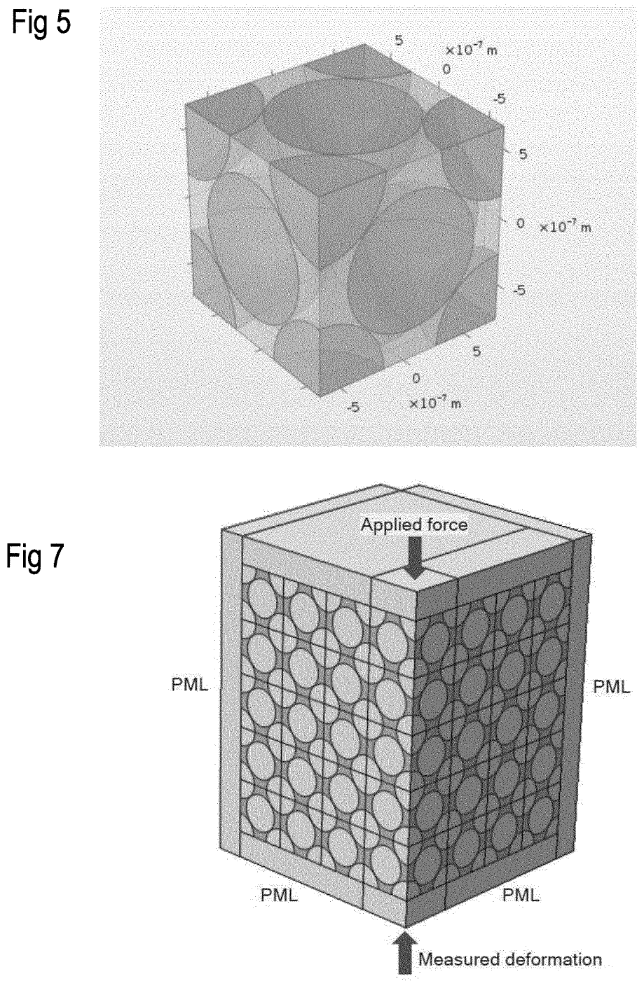

FIG. 5 shows a schematic base cell of a phononic crystal

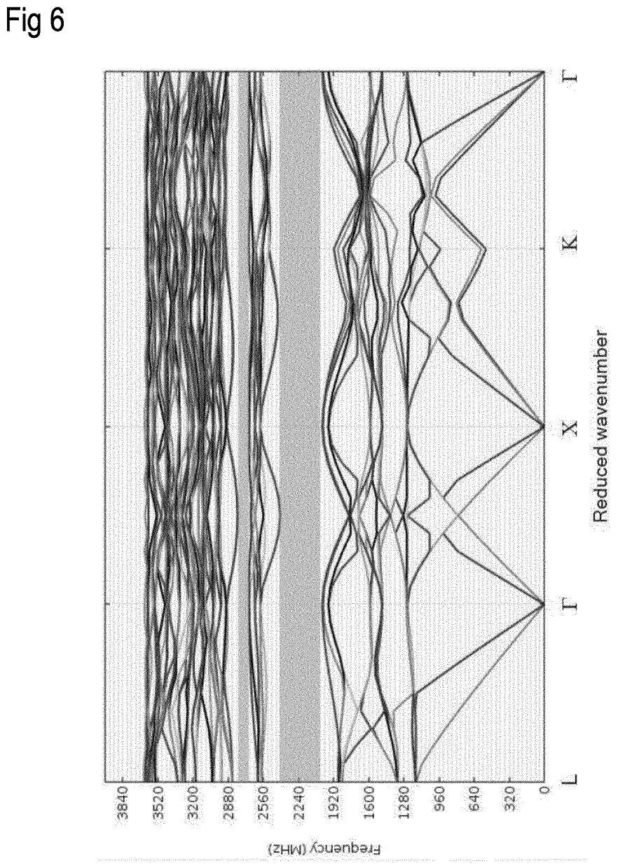

FIG. 6 shows the wavenumbers of different modes dependent on the spatial direction of propagation and on the assigned frequency

FIG. 7 shows a model on which a calculation of transmission behavior can be calculated

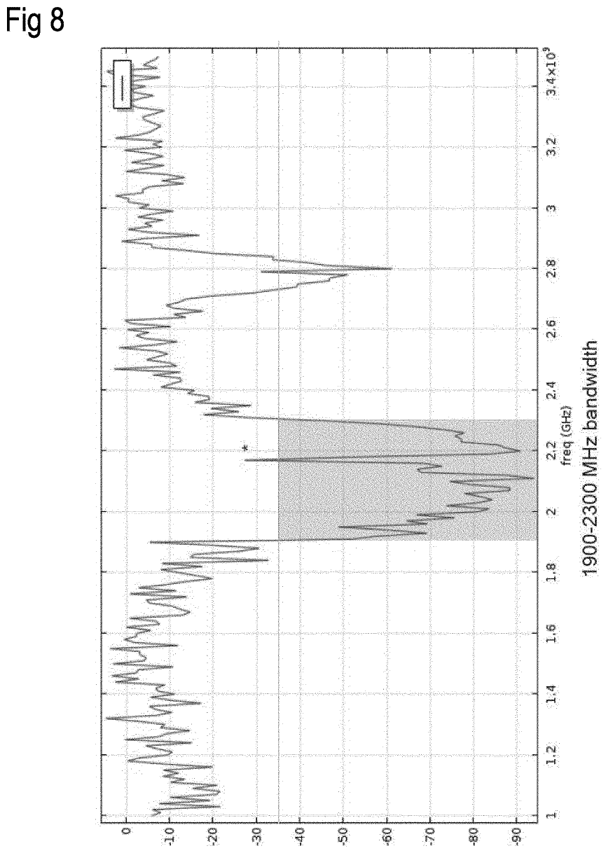

FIG. 8 shows the transmission curve of the phononic crystal material of FIG. 5 wherein the band gap is set at an RF frequency

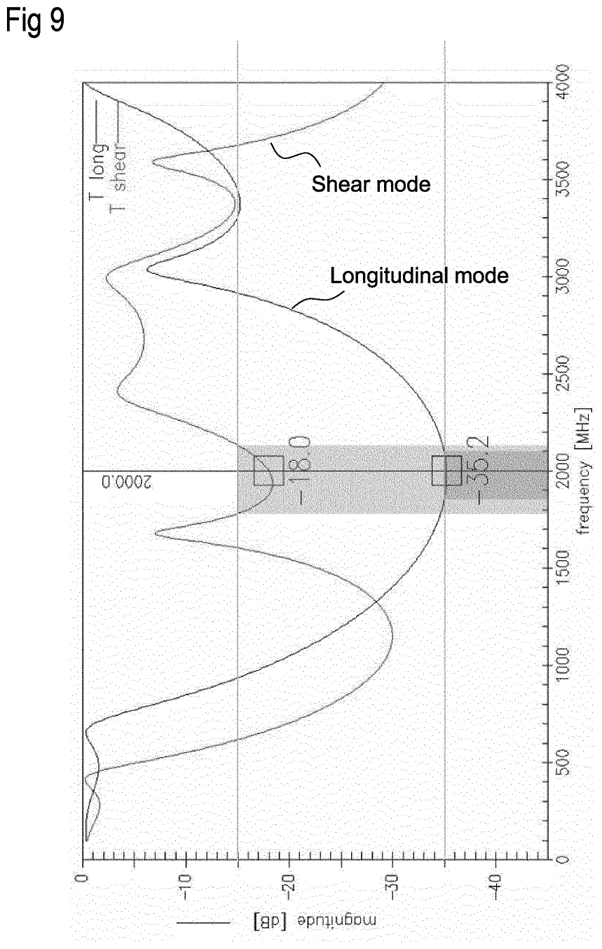

FIG. 9 shows the transmission curve of a current Bragg mirror

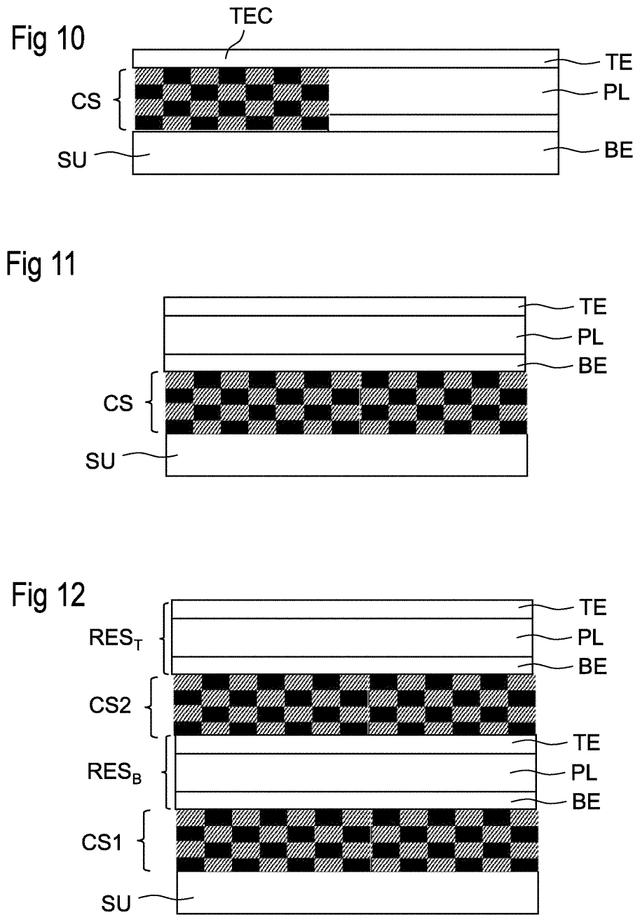

FIG. 10 shows a BAW resonator with a lateral energy confinement structure

FIG. 11 shows a BAW resonator with a vertical energy confinement structure between resonator and substrate

FIG. 12 shows two stacked BAW resonator with a decoupling confinement structure between the two resonators

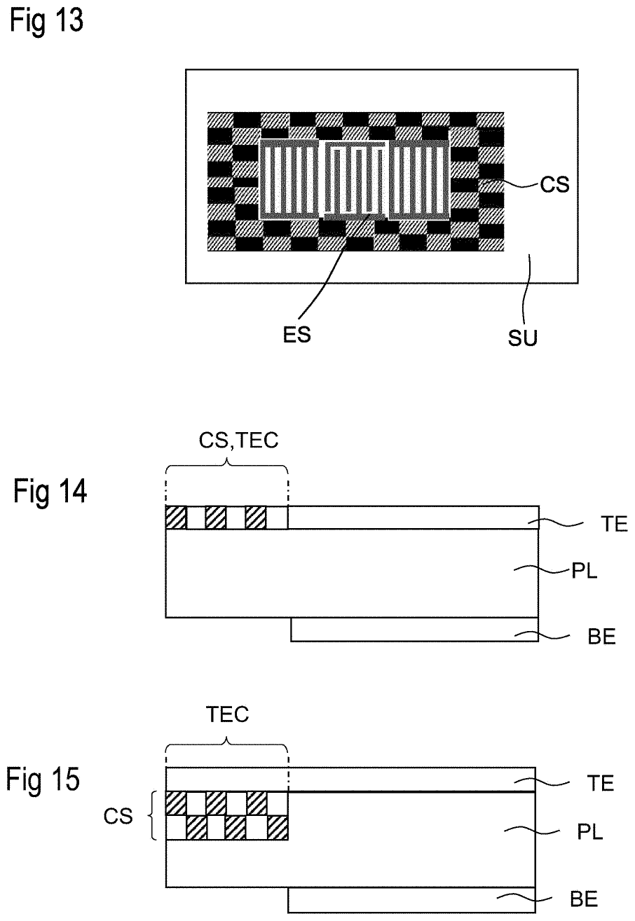

FIG. 13 shows a SAW device with a lateral confinement structure

FIG. 14 shows a BAW resonator with an electrically conducting phononic crystal material structured to form a top electrode connection of the BAW resonator

FIG. 15 shows a BAW resonator with top electrode connection and a phononic crystal material arranged below the top electrode connection.

A first method of manufacturing a phononic crystal material that is useful for forming a confinement structure at a micro-acoustic device is explained with reference to FIGS. 1A to 1D. Each figure shows a stage of the process.

The process starts with a substrate SU that may be a conventional carrier of a mechanically stable material with desired thermomechanical properties. On this carrier a layer of a functional material can be deposited. Alternatively the substrate may completely be comprised of a functional material like a piezoelectric wafer for example. Further, the substrate can have functional device structures of a micro-acoustic device for example electrode structures of a SAW or a BAW device.

On this substrate SU a layer of a first material M1 is deposited by a suitable deposition process as shown in FIG. 1A. The first material may be a metal, a ceramic layer or a resin like a polymer or any other layer forming material that is compatible with the device and the process of manufacture. The M1 layer is then patterned by e.g. selective etching of first material to form a periodic grid of repeating units RU1. The pattern may comprise stripes extending in one direction only. Further, the pattern may be two-dimensional like a checkerboard.

The dimensions of the repeating units and their distances as well are chosen to be near the wavelength of the acoustic wave that has to be reflected that is the wavelength corresponding to the bandgap of the phononic crystal material to be produced.

The pattern shown in FIG. 1B is already configured to act like a conventional acoustic mirror but possibly does not yet provide a phononic band gap. The mirror is working in a horizontal direction. However, filling the gaps or voids between the repeating units RU1 of first material M1 is preferred. Hence, a second material M2 is deposited over the entire surface of the arrangement as shown in FIG. 1C. The second material M2 is different to the first material M1 and shows a strongly differing acoustic impedance. The second material may be applied as a liquid. Alternatively the second material may be applied as a solid e.g. by a vapor phase deposition process like sputtering, CVD, plasma deposition, evaporating and the like.

In the shown case the second material M2 is applied into the gaps but extends over the repeating units RU1 of the first material. Hence, a planarizing step follows. E.g. a CMP (chemical mechanical polishing) can be conducted to remove excess second material to provide a plane surface where first and second repeating units RU1, RU2 are alternating in one or two dimensions as shown in FIG. 1D.

FIGS. 2A to 2D show different process stages during a second manufacturing process. On the top surface of a substrate SU as shown in FIG. 2A a first monolayer of monodisperse, spherical microbeads MB out of a first material is deposited e.g. by means of Langmuir-Blodgett technique. To do so, a self-assembling process can be used. Such a process provides a dense and periodic arrangement of micro beads and needs not be structured or patterned anymore. FIG. 2B shows the monolayer of microbeads MB.

In the next step the gaps or voids between the microbeads are filled with a second material M2. A liquid material can be applied easily and hence, a liquid resin like an epoxy is preferred. After filling the gaps/voids completely the so-produced layer is cured to transform the resin into a solid state wherein the micro-beads MB are embedded in forming a stable layer of phononic crystal material as shown in FIG. 2C.

On the plane surface achieved after curing a second and further layers can be produced to form a three-dimensional structure of the phononic crystal material. FIG. 1D exemplary shows three layers. However more layers can be applied dependent on the desired height of the phononic crystal material respectively of the confinement structure formed therefrom.

A relation between the dimensions of the repeating units and the frequency of the phononic band gap can be shown as follows. In an example the sound velocity in a piezoelectric material is about 10,000 m/s. Hence, at a frequency of 2 GHz a wavelength of about 5 μm results. With repeating units formed by the above described micro beads having a diameter of 1 μm and being embedded in an epoxy material a phononic band gap at about 2 GHz can be achieved.

FIGS. 3A to 3F show different process stages during a third manufacturing variant. FIGS. 3A to 3D depict the same steps as shown in FIGS. 1A to 1D to result in an alternating pattern of first and second repeating units RU1 and RU2 that together form a layer with a plane surface. Thereon a layer of the first material is deposited as shown in FIG. 3E and patterned by a suitable structuring method. A lithography may be used. In the second layer, the repeating units are shifted relative to their respective arrangement in the first layer such that second repeating units RU2 of the second layer are placed directly over first repeating units RU1 in the first layer. Repeating the steps according to FIGS. 1A to 1D results in a three-dimensional periodic arrangement as shown in FIG. 3F.

With reference to FIGS. 4A to 4D a further method is shown. Additive manufacturing of 3D structures allows sub-μm sized structures e.g. printed into a photoresist metal precursor by means of two-photon lithography. Replacing the non-exposed photoresist by a liquid dielectric precursor (e.g. TEOS) followed by a subsequent annealing step leads to a shrinking of the structure with a well-defined ratio.

In the 3-D printing process the phononic crystal material can be produced in a desired thickness as a two- or three-dimensional pattern. On a substrate SU the 3-D pattern is formed directly by 3-D printing. In a first variant first repeating units RU1 are arranged alternatingly with empty gaps that remain between the first repeating units RU1 as shown in FIG. 4B. These gaps/voids can be filled with a second material M2 that is applied in liquid form and cured afterwards. FIG. 4C shows the respective arrangement before and FIG. 4D after curing.

According to a second variant the 3-D printing process can be used to form the structure of first and second repeating units in parallel and directly as shown in FIG. 4D. First and second material can be chosen to provide a desired difference of the respective acoustic impedances.

After forming the phononic crystal material in a block form a further patterning process can be used to produce a confinement structure of a desired shape. Such shaping or structuring may be required if there are already existing device structures on the substrate and the confinement structure needs to be arranged at a specific location with a limited dimension. At applications where the confinement structure is applied as a layer over the complete substrate or device no structuring is required.

In the following the bandgap effect and properties of a phononic crystal material is explained with reference to a model and respective calculation based on this model.

FIG. 5 shows a structure formed by a dense arrangement of spherical bodies of a first material (SiO₂) embedded in a matrix of a second material (epoxy). Within this model different spatial directions can be defined to calculate the behavior of the phononic crystal along these spatial directions. The spherical bodies have a diameter of about 1 μm and the depicted base cell has a diameter of about 1.5 μm. The fcc lattice in this base cell has an r/a ratio of 0.35.

FIG. 6 shows a dispersion diagram. It becomes apparent the depicted modes show varying frequencies in different spatial directions. But there is a band gap between 1900 MHz and 2300 MHz where neither excitement nor propagation of any acoustic mode occurs. A further bandgap can be found around 2800 MHz.

Transmittance for acoustic waves of such a structure is calculated with reference to a model shown in FIG. 7. In the model a cube of phononic crystal material is enclosed by perfectly matched layers such that the results are applicable for a bulk of infinite spatial extension. Onto a limited surface area on the top surface in the center of the depicted cube a mechanical force is applied with a varying frequency. At the bottom and hence opposite to the area where the force is applied to the deformation is calculated.

The result is shown in FIG. 8. The curve depicts the calculated transmittance of acoustic waves in this model structure. Within the bandgap the transmittance decreases to values below −50 dB while for the remaining spectrum high transmittance of about −10 dB and more is achieved. Hence, transmittance complies with calculated propagation of modes as shown in FIG. 7.

FIG. 9 shows the transmittance of a Bragg mirror that is currently used as an acoustic mirror in current BAW devices. The lower curve corresponds to the longitudinal mode and the upper curve to the respective shear mode. The horizontal line at −35 dB corresponds to the maximal transmittance for longitudinal waves in the reflector band of a Bragg mirror.

FIG. 8 proves that the phononic crystal shows higher reflectivity in the band gap and hence less transmissivity than a conventional Bragg mirror. It is hence quite advantageous to replace the Bragg mirror of a BAW device by a confinement structure made of a phononic crystal as described.

FIG. 10 shows an embodiment of a micro acoustic device embodied as a BAW resonator using a lateral confinement structure CS consisting of a phononic crystal material. The BAW resonator comprises a bottom electrode BE, a piezoelectric layer PL and a top electrode TE. Between bottom electrode and substrate an acoustic mirror is arranged (not shown) to avoid acoustic losses to the bulk of the substrate. The top electrode TE extends beyond the active resonator area where bottom electrode BE, piezoelectric layer PL and a top electrode TE overlap each other. This extension is structured to provide a top electrode connection TEC to electrically contact another resonator or a terminal of the BAW resonator. As this top electrode connection TEC is prone to acoustic losses by excitement of spurious lateral modes a confinement structure CS consisting of a structured phononic crystal material is arranged on the substrate below the top electrode connection TEC. By such an arrangement acoustic losses of the top electrode connection TEC can be reduced substantially.

FIG. 11 shows a further embodiment wherein a confinement structure CS consisting of a layer of a phononic crystal material substitutes the commonly used Bragg mirror on the substrate below the bottom electrode BE. Such a layer may comprise five layers of repeating units that are sufficient to provide the required reflection within the band gap.

FIG. 12 shows another embodiment wherein a confinement structure CS2 consisting of a layer of a phononic crystal material is used to acoustically decouple two BAW resonators REST, RESB stacked one above the other on a substrate SU. A further confinement structure CS1 consisting of a layer of a phononic crystal material is used as an acoustic mirror on the substrate SU. Each BAW resonator RES comprises a bottom electrode BE, a piezoelectric layer PL and a top electrode TE. As each such intermediate confinement layer can be produced with a plane surface the stacked arrangement is not limited to two stacked resonators.

FIG. 13 is an embodiment where a structured confinement layer CS out of a phononic crystal material is deposited onto the piezoelectric layer PL of a SAW device to provide a lateral energy confinement causing the acoustic energy to be confined to the acoustic path. Though showing a confinement structure CS that completely surrounds the acoustic path it is also possible to place such a structure only at the lateral along the busbars of the electrode structures ES or at the longitudinal ends of the acoustic path comprising IDT and/or reflector. In a sophisticated arrangement it is possible to replace the reflectors by a confinement structure out of a phononic crystal material.

FIG. 14 shows an embodiment of a micro-acoustic device with a phononic crystal. A BAW resonator comprises a bottom electrode BE, a piezoelectric layer PL and a top electrode TE. An active resonator volume is the volume where all three layers overlap each other. For forming a top electrode connection the top electrode TE is laterally elongated by an electrically conducting confinement structure CS formed by a phononic crystal material.

FIG. 15 shows a similar embodiment of a micro-acoustic device. Here too the BAW resonator comprises a bottom electrode BE, a piezoelectric layer PL and a top electrode TE. An active resonator volume is the volume where all three layers overlap each other. The top electrode TE is elongated to laterally extend over the active resonator volume thereby forming a top electrode connection. A confinement structure CS formed by a dielectric phononic crystal material is arranged below the top electrode connection. The confinement structure prevents acoustic waves from leaking out of the top electrode connection TEC.

The invention may not be limited by the specific figures and embodiments but is only defined by the scope of the claims.

List of used terms and reference symbols

| | |
|---|---|
| | micro-acoustic device |
| SU | substrate |
| | top surface of substrate |
| PL | piezoelectric layer |
| ES | electrode structure |
| | operation frequency |
| | acoustic path |
| | active volume |
| CS | confinement structure |
| | phononic crystal material |
| | patterned structure |
| | periodic grid |
| RU | repeating unit |
| | gap |
| M₁ | first solid material, embedded in a |
| M₂ | second solid material |
| | BAW resonator |
| | arrangement of BAW resonators |
| | Rx filter |
| | Tx filter |
| TEC | top electrode connection |
| BE | bottom electrode connection |
| | acoustic mirror |
| | thin film SAW device |
| MB | micro-beads |
| RES | resonator |

1. A micro-acoustic device comprising:
a substrate (SU);
a piezoelectric layer (PL) on a top surface of the substrate;
an electrode structure on the piezoelectric layer for exciting acoustic waves at an operation frequency propagating along an acoustic path or within an active volume of the piezoelectric layer; and
a confinement structure (CS) adapted to block propagation of acoustic waves at the operation frequency to confine the acoustic waves to the acoustic path or the acoustic volume, the confinement structure being arranged:
at a position lateral to the acoustic path; and/or
between substrate and piezoelectric layer; and/or
on the top surface of the electrode structure or the piezoelectric layer.

2. The micro-acoustic device of claim 1,
wherein the confinement structure comprises a phononic crystal material that has a patterned structure along at least one dimension according to a periodic grid
wherein the grid like patterned structure comprises repeating units (RU) of a first solid material (M1) embedded in a second solid material (M2), first and second material being different in at least one of material, density, acoustic impedance, velocity of acoustic wave, stiffness, E-modulus and hardness
wherein the size and distance of the repeating units is chosen to achieve a phononic band gap at the desired operation frequency.

3. The micro-acoustic device of claim 1,
wherein the micro-acoustic device comprises an arrangement of BAW resonators arranged on a common substrate
wherein acoustic coupling between different BAW resonators is avoided by arranging the confinement structure between the different BAW resonators and/or below the resonators between resonator and substrate.

4. The micro-acoustic device of claim 1,
wherein the micro-acoustic device comprises an arrangement of BAW resonators stacked one above the other on a common substrate
wherein the confinement structure comprises a layer arranged at the interface between two stacked BAW resonators.

5. The micro-acoustic device of claim 1,
wherein the micro-acoustic device comprises a thin film SAW device comprising an acoustic path within the piezoelectric layer and arranged on the substrate
wherein a layer of the confinement material is arranged laterally adjacent to the acoustic path of the SAW device.

6. The micro-acoustic device of claim 1, further comprising:
a substrate with a layer of confinement material on the top surface thereof
different micro-acoustic RF filters arranged on the same substrate above the layer of confinement material
wherein the RF filters comprise an Rx and a Tx filter that are mutually acoustically isolated by a layer of confinement material.

7. The micro-acoustic device of claim 1, further comprising an arrangement of circuited BAW resonators arranged adjacently on a common substrate
wherein the BAW resonators are circuited via a top electrode or a bottom electrode connection
wherein top electrode or a bottom electrode connection are formed from an electrically conducting phononic crystal material.

8. A method of manufacturing a micro-acoustic device, comprising:
on a substrate, forming a piezoelectric layer and an electrode structure of the micro-acoustic device adapted to excite acoustic waves at an operation frequency in an acoustic path or an active volume; and
forming a confinement structure in the form of a phononic crystal material to block propagation of acoustic waves at the operation frequency to confine the acoustic waves to the acoustic path or the active volume;
wherein forming the confinement structure of phononic crystal material comprises:
a) applying a first layer of repeating units of a first solid material according to a periodic grid onto the substrate or any other device structure already formed on the substrate;
b) filling gaps between the repeating units with a liquid material;
c) transforming the liquid material into a solid second material by hardening or solidifying the liquid material to achieve repeating units of second material; and
d) optionally planarizing and structuring the layer to yield a solid and plane layer of repeating units of alternating first and second material.

9. The method of claim 8, wherein step a) comprises:
a1) applying a continuous layer of first material; and
a2) structuring the continuous layer to result in a periodic grid of repeating units of the first solid material;
wherein step b) comprises:
b1) filling a liquid resin material onto the grid until at least all gaps between the repeating units are filled;
wherein step c) comprises curing the resin by applying heat to the arrangement; and
wherein step c) optionally comprises a CMP method.

10. The method of claim 9, further comprising, after planarizing, repeating steps a) to d) to achieve a three-dimensional periodic pattern of the phononic crystal.

11. A method of manufacturing the micro-acoustic device, comprising:
on a substrate, forming a piezoelectric layer and an electrode structure of the micro-acoustic device adapted to excite acoustic waves at an operation frequency in an acoustic path or an active volume; and
forming a confinement structure in the form of a phononic crystal material to block propagation of acoustic waves at the operation frequency to confine the acoustic waves to the acoustic path or the active volume by printing a three-dimensional periodic pattern with 3D printing technique, the pattern comprising repeating units of a first solid material embedded in a second solid material.

12. A method of manufacturing a micro-acoustic device comprising:
on a substrate, forming a piezoelectric layer and an electrode structure of the micro-acoustic device adapted to excite acoustic waves at an operation frequency in an acoustic path or an active volume; and
forming a confinement structure in the form of a phononic crystal material to block propagation of acoustic waves at the operation frequency to confine the acoustic waves to the acoustic path or the active volume,
wherein forming the confinement structure comprises:
depositing monodisperse spherical microbeads are on the substrate in a self-assembling process;
filling the gaps between the microbeads with a liquid polymer material;
hardening the liquid polymer to transform it into a solid second material thereby yielding a layer of a 2D phononic crystal;
optionally planarizing and structuring the layer to yield a solid and plane layer of repeating units of alternating first and second material; and
optionally repeating the above steps to form at least one further layer of a 2D phononic crystal wherein the repeating units in the second layer and optionally further layers are respectively offset to the layer below.
